(19) United States
(12) Patent Application Publication
(10) Pub. No.: US 2012/0264020 A1
(43) Pub. Date: Oct. 18, 2012

(54) METHOD OF DEPOSITING SILICON ON CARBON NANOMATERIALS

(75) Inventors: David J. Burton, Waynesville, OH (US); Max L. Lake, Yellow Springs, OH (US); Maryam Nazri, Bloomsfield Hills, MI (US); Andrew C. Palmer, Piqua, OH (US)

(73) Assignee: Applied Sciences, Inc., Cedarville, OH (US)

(21) Appl. No.: 13/269,201

(22) Filed: Oct. 7, 2011

Related U.S. Application Data
(60) Provisional application No. 61/390,800, filed on Oct. 7, 2010.

(51) Int. Cl. H01M 4/583; C23C 16/02; C23C 14/35; B29D 99/00; B05D 7/00; C23C 16/24; B82Y 30/00

(52) U.S. Cl. 429/231.8; 427/215; 427/248.1; 427/214; 427/249.1; 204/192.15; 264/105; 977/891; 977/948

(57) ABSTRACT

A method of depositing silicon on carbon nanomaterials such as vapor grown carbon nanofibers, nanomats, or nanofiber powder is provided. The method includes flowing a silicon-containing precursor gas in contact with the carbon nanomaterial such that silicon is deposited on the exterior surface and within the hollow core of the carbon nanomaterials. A protective carbon coating may be deposited on the silicon-coated nanomaterials. The resulting nanocomposite materials may be used as anodes in lithium ion batteries.

### CROSS REFERENCE TO RELATED APPLICATIONS

This application claims the benefit of U.S. Patent Application Ser. No. 61/390,800, entitled METHOD OF DEPOSITING SILICON AND SULFUR ON CARBON NANOMATERIALS AND FORMING AN ANODE AND CATHODE FOR USE IN LITHIUM ION BATTERIES filed Oct. 7, 2010. This application also claims the benefit of U.S. patent application Ser. No. 12/107,254, entitled METHOD OF DEPOSITING SILICON ON CARBON MATERIALS AND FORMING AN ANODE FOR USE IN LITHIUM ION BATTERIES filed Apr. 22, 2008. The entire contents of said applications are hereby incorporated by reference.

### BACKGROUND OF THE INVENTION

Embodiments of the invention relate to a method of depositing silicon on the exterior surface and within the hollow core of carbon nanomaterials such as vapor grown carbon nanofibers, nanomats and nanofiber powders to produce high capacity electrodes having high capacity retention rates for use in lithium ion batteries.

The automotive industry is currently pursuing energy storage technologies which will enable the production of hybrid and electric-based vehicles with superior performance characteristics in comparison with internal combustion engines at the same or lower cost of production.

The use of lithium ion battery technology represents a promising energy storage solution as lithium ion batteries have the highest energy density of all rechargeable electrochemical storage devices. However, currently available lithium-ion battery technologies are limited to system level energy densities of less than 200 Wh/kg, which results in unacceptably short driving range for most automobile owners. In addition, lithium ion batteries have a short cycle life and are expensive to produce, leading to high lifetime costs for the consumer.

It would be desirable to use alternative anode and cathode materials which exhibit higher specific capacities than currently used materials. Current lithium ion batteries typically use lithium cobalt oxide as the cathode and carbon or graphite as the anode. Recent research indicates that materials which form alloys with lithium provide a significant improvement in the energy density of current anode materials made from carbon alone. Silicon, which has a theoretical capacity of up to 4200 mAh/g, is one such material; however, silicon-based anodes exhibit a rapid loss of capacity after the first few charge-discharge cycles. This occurs due to alternating volume expansions and contractions which induce mechanical stress and fracturing of the Si particles, resulting in the loss of electrical contact from the anode structure.

Nano-silicon/carbon composites have also shown promise for anodes as they exhibit the high energy capacity of silicon combined with the long cycle life of carbon; however, such materials still suffer from reduced energy capacity from cycling.

Accordingly, there is still a need in the art for a method of incorporating high capacity elements such as silicon with carbon nanomaterials which can be used to make an improved anode for use in a lithium ion battery.

### SUMMARY OF THE INVENTION

Embodiments of the invention meet that need by providing a method of depositing a durable nano-scale silicon coating or layer on the interior and exterior surfaces of carbon nanomaterials such as vapor grown carbon nanofibers, nanomats, or nanofiber powders. The resulting silicon-coated nanomaterial may be used as an anode in a lithium ion battery.

The method also includes the nano-scale deposition of a protective carbon coating to the silicon-coated carbon nanomaterials to increase the cycling efficiency of silicon and to increase capacity.

According to one aspect of the invention, a chemical vapor deposition method is provided for depositing silicon onto a carbon nanomaterial. The method includes providing a carbon nanomaterial selected from vapor grown carbon nanofibers, a carbon nanomat, and a carbon nanofiber powder; and flowing a silicon-containing precursor gas in contact with the carbon nanomaterial for a time sufficient for the gas to decompose and form a silicon coating on the interior and exterior surfaces of the carbon nanomaterial.

By “carbon nanofiber,” it is meant a generally hollow cylindrical nanostructure with one or more graphene layers. By “carbon nanomat,” it is meant a conductive network of carbon nanofibers held together with a carbonizable binder such as epoxy or polyester. The carbon nanofibers may optionally include carbon fibers such as those based on polyacrylonitrile (PAN). By “carbon nanofiber powder,” it is meant a powder comprised of micron-sized agglomerates of entangled carbon nanofibers.

The precursor gas is flowed in contact with the carbon nanomaterial at a temperature between about 400° C. to about 1200° C., and more preferably, between about 400° C. to about 700° C. The precursor gas comprises sine, a blend of silane and hydrogen, or a blend of silane and an inert gas.

The silicon coating formed on the nanomaterial comprises crystalline silicon or amorphous silicon. The silicon is coated onto the carbon nanomaterial at a thickness of about 2 to 100 nm, and more preferably, at a thickness of about 20 to 50 nm.

The nanofibers comprising the carbon nanomaterial preferably have an average length of from about 1 to about 500 micrometers, and more preferably, from about 10 to about 100 microns.

In one embodiment, the method further includes applying a protective carbon coating to the silicon-coated carbon nanomaterial. The carbon coating may be applied by carbonization, chemical vapor deposition, or magnetron sputtering. The coating is preferably applied by magnetron sputtering to a thickness of about 5 to 10 nm.

In yet another embodiment, the method includes applying a plurality of alternating layers of silicon and carbon coatings to the carbon nanomaterial.

In another embodiment, the method further includes exposing the silicon-coated nanomaterial to an oxidizing gas for a time sufficient to oxidize the silicon coating and form a silicon oxide coating. The oxidizing gas is preferably selected from carbon dioxide and oxygen. The silicon-coated nanomaterial is preferably exposed to the oxidizing gas at a temperature of about 200° C.

The method may further include heating the carbon nanomaterial at a temperature between about 100° C. to 1200° C. in the presence of an oxidizing gas prior to depositing the silicon coating. The carbon nanomaterial is heated for a time sufficient to increase the surface area of the carbon nanomaterial. This step also increases the pore volume of the carbon nanomaterial. The oxidizing gas is preferably selected from carbon dioxide and oxygen.

The resulting silicon-coated nanomaterial may be formed into an anode for use in a lithium ion battery by blending the coated nanomaterial with a binder. The binder is preferably selected from polyvinylidene fluoride, furfuryl alcohol, and polystyrene.

The resulting anode preferably has an electrical conductivity of from 0.01 ohm/cm to 0.5 ohm/cm, and a thermal conductivity of at least 50 W/m-K up to 1000 W/m-K. The anode has an irreversible capacity of from less than about 5% to 40% of total capacity, and a reversible capacity of at least 450 milliamp hour/gram (mAh/g).

The anode containing the silicon-coated carbon nanomaterial may be incorporated into lithium ion batteries for a number of uses. For example, lithium-ion batteries containing the anode may be used to extend the range of hybrid and electric vehicles.

Accordingly, it is a feature of embodiments of the invention to provide a method of depositing silicon on the interior and exterior surfaces of carbon nanomaterials such as vapor grown carbon nanofibers, carbon nanomats, and nanofiber powder, and to an anode produced from such coated nanomaterials. It is also a feature of embodiments of the invention to provide a method of depositing silicon on carbon nanomaterials followed by the application of a protective carbon coating or oxidizing the surface of the silicon coating. Other features and advantages of the invention will be apparent from the following description, the accompanying drawings, and the appended claims.

### BRIEF DESCRIPTION OF THE DRAWINGS

FIG. 1 is schematic illustration of an end view of a carbon nanofiber illustrating a silicon coating deposited according to an embodiment of the invention;

FIG. 2 is a graph illustrating the cycling performance of a silicon-coated carbon nanomat including an overcoat of carbon;

FIG. 3 is a graph illustrating the cycling performance of a silicon-coated carbon nanomat including an overcoat of carbon;

FIG. 4 is an EDS line-scan across the diameter of a silicon coated nanofiber which illustrates the concentration and distribution of silicon and carbon;

FIG. 5 is a schematic illustration of an end view of a carbon nanofiber illustrating alternating layers of silicon and carbon coatings according to an embodiment of the invention; and

FIG. 6 is a graph illustrating the cycling performance of a carbon nanomat coated with multiple silicon and carbon coatings.

### DETAILED DESCRIPTION OF THE PREFERRED EMBODIMENTS

We have found that deposition of silicon onto the interior and exterior surfaces of carbon nanomaterials is a reliable method for producing anodes with high capacity and cycling stability. By depositing the silicon within the hollow core of the nanofiber, a compositionally graded interface is formed between the deposited silicon coating and carbon nanofibers which provides a bond that can survive extended cycling. By “graded interface,” it is meant the compositional transition from pure graphite to silicon carbide to silicon (or silicon oxide; where the silicon coating is further exposed to oxidizing conditions).

In addition, as the silicon is deposited within the core of the nanofibers, this contributes to the overall capacity as the silicon remains encapsulated by the walls of the nanofibers during cycling. The deposition of a nano-scale, amorphous layer of silicon is also capable of accommodating the stresses generated by the volume changes that occur during lithiation and de-lithiation when used as an anode in lithium ion batteries.

In addition, when carbon is subsequently deposited on the silicon coated nanomaterials, this coating inhibits the fracture and separation of silicon. The carbon coating also functions to contain the silicon, maintain connectivity to the current collector, and contribute to capacity.

The resulting silicon-coated nanomaterial exhibits high energy capacity and high power capability when used as an anode in a lithium ion battery cell. The anode provides a significant increase in energy capacity up to 1000 mAh/g or higher for greater than 100 charge-discharge cycles. The use of such an anode provides a low irreversible capacity loss upon cycling and provides a boost in reversible and total charge capacity over that observed with the use of graphitic materials alone.

The silicon used in the method may be derived from a variety of gas phase silicon bearing compounds including, but not limited to, methyl trichlorosilane and SiH₄. Preferred precursor gases include silane, a blend of silane and hydrogen, or blends of silane and an inert gas such as helium, nitrogen or argon. Silicon deposition may be performed at atmospheric pressure, at reduced pressure, or at an elevated pressure which is raised with respect to atmospheric pressure in order to control the rate and properties of the deposited silicon coating.

The resulting silicon coating may comprise crystalline silicon or amorphous silicon. Amorphous silicon is preferred as it is believed to be deposited in a nanoscale domain such that nanoscale particles of amorphous silicon are incorporated into a graded interface and are mechanically bound to the surface of the nanofibers. Further, amorphous silicon is more resistant to fracturing than crystalline silicon during the volume changes that occur during charge/discharge cycles of the battery.

The silicon may be coated onto the carbon nanomaterial at a thickness ranging from 1 to 1000 nanometers, which may be varied by changing the exposure time and/or adding diluent gases. The coating thickness is about 2 to 100 nm, and most preferably, about 20 to 50 nm. It should be appreciated that the nature of the coating can vary from unconnected islands of silicon to a continuous coating.

It should be appreciated that the method of depositing silicon results in a graded interface. By exposing the graphitic carbon nanofibers to silane at a temperature which causes decomposition of the silane, silicon is deposited on the surface of the fiber and reacts with the carbon atoms on the surface of the fiber to form silicon carbide. Further deposition of silicon on the silicon carbide surface results in a graded interface between the interior graphite structure and the external silicon coating.

Preferred nanofibers for use in the method are vapor grown carbon nanofibers comprised of long filaments having a graphitic nature. Suitable nanofibers include Pyrograf® III, commercially available from Applied Sciences, Inc. and Pyrograf Products, Inc. The preferred carbon nanofibers are essentially comprised of a graphitic hollow tube, referred to as the catalytic phase of the carbon nanofiber, and having essentially no turbostratic or disordered carbon on the surface of the nanofiber. This type of nanofiber is preferred as it is highly electrically conductive and has a high surface area of about 10 to 200 m²/g, and preferably about 20 to 100 m²/g, and a surface energy of about 60 to 185 mJ/m². The carbon nanofibers preferably have a length of from about 1 to about 500 micrometers, and more preferably, from about 10 to 100 micrometers in order to provide a sufficiently entangled and durable anode.

The vapor grown carbon nanofibers are preferably heat treated prior to use in order to remove contaminants such as iron. Heat treatment is preferably performed in an inert atmosphere at a temperature above 700° C., and more preferably between about 1500° C. and 3000° C.

Carbon and graphite additives may be added to the carbon nanomaterial prior to the silicon coating step to increase the electrical conductivity and capacity of the resulting anode. Such additives may be selected from single-walled carbon nanotubes, multi-walled carbon nanotubes, exfoliated graphite flakes, graphite platelets, graphene particles, carbon black, and mesocarbon microbeads. The additives may be added as a dry powder or by incorporation with a solvent to form a slurry. Such additives may be added by conventional techniques for incorporating solids into liquid solutions such as planetary and impeller type mixers.

A conductive additive may also be added to the carbon material before the silicon coating step to provide electrical and thermal conductivity as well as mechanical reinforcement to the resulting anode. The conductive additive may be added to the carbon material by blending as a dry powder or by incorporation with a solvent to form a slurry. A preferred additive is macroscopic vapor grown carbon fibers having a diameter of from about 500 nm to 10 micrometers. Such vapor grown carbon fibers are highly graphitizable and may be added in selected proportions of about 1 to 90% by weight and more preferably, about 5 to 50% by weight to provide the desired reinforcement and thermal conductivity.

The nanocarbon material, along with any of the additives described above, is preferably fabricated into the form of a nanofiber mat or powder prior to the silicon coating process.

For example, macroscopic vapor grown carbon fibers may be incorporated with carbon nanofibers to fabricate nanomats with improved mechanical properties as well as to impart high electrical and thermal conductivity. Such mats, when coated with silicon, may be suitable as an integrated electrode and current collector. Where macroscopic vapor grown carbon fibers are blended with the nanocarbon material, such fibers are preferably incorporated into preforms from the as-grown state, which reduces the number of high temperature annealing treatments needed as well as allowing fabrication of the preforms while the fibers are in the “green” non-graphitized state, resulting in less fiber damage through handling. Alternatively, the macroscopic vapor grown carbon fibers may be heat treated prior to fabrication of the preform so that no further heat treatment is required. This allows elastomeric binders or other binders which will not survive heat treatment to be used to fabricate the composite preforms.

Chemical binders may be used to hold the fibers in place within the composite preform. Alternatively, elastomeric binders may be used to impart flexibility if no further heat treatment is required, or graphitizable binders such as polymerized furfuryl alcohol may be used as a solvent suitable for dispersing carbon nanofibers. For example, appropriate lengths of vapor grown carbon nanofibers may be spread by hand on the base of a compression mold in the desired fiber lay-ups. The thin layers of the aligned fibers are then saturated with binder and placed in a mold, with the molding being programmed for a specific time-temperature-pressure cycle. The fiber volume in the preforms is controlled by compression to prescribed volumes using mold stops. After molding, the resulting panels are trimmed, measured, and weighed. Following densification and heat treatment, the panels are machined to specimen size for further processing. Carbonization of the panels is then performed by framing the panels between graphite plates and slowly heating the panels to 1000° C. (1832° F.) in a purified argon atmosphee. This process is generally carried out over a 3 to 4 day period.

In an alternative method of forming a preform comprised mainly of carbon nanofibers, the carbon nanofibers (along with any additives) are combined in solution by mixing and dispersing the suspension using sonication or other low shear/high energy methods. Following dispersion, the carbon material suspension is poured over a vacuum-assisted filtration system. Preforms are allowed to dry in the system and are then collected. Where the preforms are fabricated with a binder, this may require additional processing such as curing or compression molding

One preferred product form for use in the silicon deposition method is a carbon nanomat formed as described above, which comprises a conductive network of carbon nanofibers with or without carbon fibers held together with a carbonizable binder such as epoxy or polyester. This product form is electrically conductive and is highly porous, allowing easy access of electrolytes to the carbon-silicon anode.

Another product form is a powder comprised of micron size agglomerates of entangled carbon nanofibers. The powder may be formed by a number of conventional methods for powder processing, including de-bulking the as-grown fibers into a pelletized from using wet mixing or powder processing methods. The fibers are typically mixed with a binder in this process.

By providing the nanofibers in powder form, silicon may be deposited using a fluidized bed reactor at lower cost, larger production volumes, and higher quality. The resulting silicon coated nanofiber powder may be converted into a paste-like product which can be painted onto copper foil for the production of anodes for large scale production of lithium ion batteries.

In the chemical vapor deposition (CVD) method of coating carbon nanomaterials with silicon, the nanofibers (in fiber form or in the form of a preform (mat)), along with any additives, are preferably placed in a vessel including at least one gas inlet and one gas outlet. The vessel is then inserted into a heating chamber, and is heated in an inert atmosphere or under vacuum at a temperature between about 100° C. to about 1200° C. A silane gas or a blend of silane gas and hydrogen, or a blend of silane gas and an inert gas such as nitrogen or argon is then flowed over and through the carbon material for about 15 seconds to about 60 minutes such that it decomposes, leaving a silicon-based coating on the interior and exterior surfaces of the nanomaterial. The deposition may be conducted at atmospheric pressure, reduced pressure, or elevated pressure so as to control the deposition rate and properties of the coating on the fibers or preform. The silane gas is then purged from the vessel with an inert gas such as nitrogen or argon and cooled.

It should be appreciated that the deposition temperature varies depending on the source gas used. Where an amorphous silicon coating is desired, a deposition temperature of from about 400° C. to 700° C. is preferred.

Where the carbon nanomaterials comprise a powder, the powder is loaded into a fluidized bed, and is fluidized in nitrogen and heated between about 300° C. to 1200° C. A silane gas or blend thereof is passed through the fluidized bed with or without the aid of an inert gas. The fluidized bed is then purged with nitrogen to remove the silane, and the powder is removed from the fluidized bed while hot or after the fluidized bed cools to room temperature.

The resulting silicon-coated nanomat or powder may be subsequently exposed to oxidizing gases to form a silicon oxide coating and/or coated with a protective carbon coating as described below.

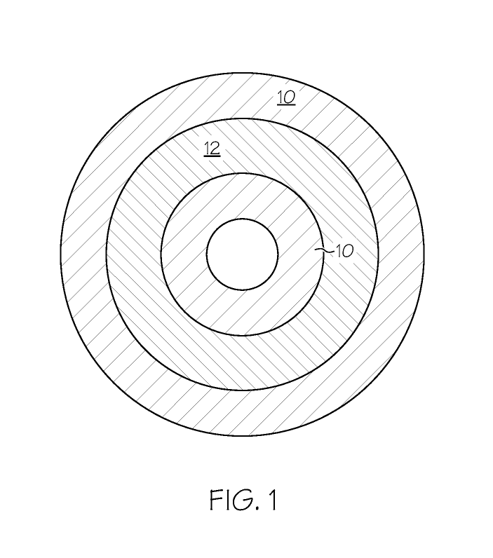

FIG. 1 illustrates the deposition of silicon on the surface of vapor grown carbon nanofibers as well as inside the fibers. As can be seen, the silicon coating 10 is present on the exterior surface as well as the interior surface of nanofibers 12.

The method of silicon deposition preferably further includes coating the silicon-coated nanomaterial with a protective carbon coating to increase the cycling efficiency of silicon by mitigating the effect of volume induced fracturing. The carbon may be deposited by coating with a carbonizable binder. For example, a solution of furfuryl alcohol (FFA) and maleic anhydride may be added drop-wise to samples of silicon coated carbon nanomats to wet the surface of the mat and then heated in air at about 220° C. for 3 hours to polymerize the deposited FFA.

Alternatively, the carbon coating may be deposited by chemical vapor deposition. For example, silicon coated nanofibers may be exposed to acetylene gas at temperatures of about 600° C. to 650° C. for about 150 minutes to generate an approximate 3% weight gain from carbon deposition.

A more preferred method of carbon coating the silicon coated nanomaterials is magnetron sputtering. For example, a silicon-coated nanomat may be deposited with a 5-10 nm thick layer of carbon via magnetron sputtering. It should be appreciated that the carbon coating may be present on the interior surface of the silicon-coated nanomaterial as well as the exterior surface. The carbon coating may also comprise a continuous or discontinuous coating.

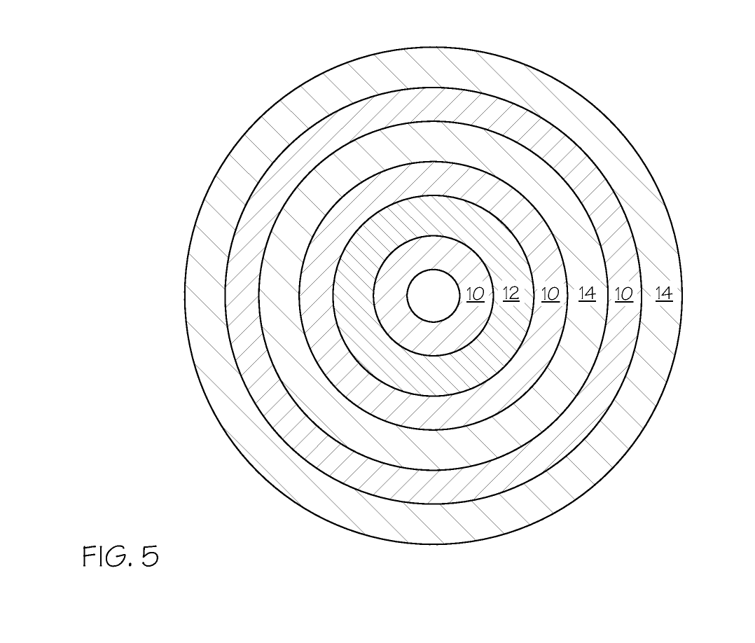

It should also be appreciated that it is possible to apply a plurality of alternating layers of the silicon and carbon coating, i.e., the silicon and carbon coating steps may be repeated. FIG. 5 illustrates this embodiment in which a carbon nanofiber 12 has been coated with alternating layers of silicon 10 and carbon 14. The alternating layers may be deposited on the exterior surface as well as the interior surface of the nanofibers.

In addition to the protective carbon coating, a silicon oxide coating may be provided on the nanomaterials by exposing the silicon-coated nanomaterial to an oxidizing gas, which causes formation of a continuous silicon oxide film which protects the silicon coating from further oxidation. In this embodiment, the silicon is preferably amorphous as it is less brittle and less susceptible to fracturing during electrochemical cycling.

Optionally, the method of silicon deposition may include oxidizing the carbon nanomaterials prior to silicon deposition to increase the surface area and total pore volume. Exposure to oxidizing gases causes conversion of some of the surface carbon on the nanofibers to carbon dioxide, which etches the surface to create open pores, which in turn increases the surface area of the fibers.

We have found that oxidizing the carbon nanomaterials prior to silicon deposition increases the surface area (as measured by nitrogen adsorption) to between about 20 m²/g to about 1000 m²/g and to increase the total nanometer scale porosity to between about 0.05 cm³/g to about 0.50 cm³/g, with pore diameters ranging from 1 to 20 nm. This increase in surface area improves the functionality of the nanofibers in several ways. First, it removes the less desirable (less graphitic) carbon layer which may be deposited on the outer wall. Second, it improves the bonding of the silicon layer on the outer walls by improving mechanical interlocking, i.e., the interphase region formed from the roughened surface upon which the silicon carbide/silicon is deposited is more mechanically robust than a coating formed on a smooth surface. The increased surface area also creates channels through the nanofiber walls which facilitate the deposition of the silicon into the preferred sites including the center channel.

An anode may be formed from the silicon-coated nanomaterials by a number of methods. In one method, the anode is formed by adding a binder to the silicon-coated carbon nanomaterial. Suitable binders include fluorinated polymers such as polyvinylidene fluoride (PVdF), furfuryl alcohol, and polystyrene. In a preferred method, the polymeric binder comprises polyvinylidene fluoride and is dissolved in an organic solvent at a 5 wt % concentration.

For silicon coated nanofiber powder samples, anodes may be made by dry blending the active material with a polyvinylidene fluoride binder dissolved in n-methyl pyrrolidone and conductive carbon to form a thick slurry paste. A 20 micron thick coating of the paste may be applied to a 10-micron thick copper foil and dried for use as a copper current collector.

For silicon coated nanomat samples, circular disks may be cut from the samples into a coin cell and inserted into a battery cell structure to function as an anode.

The resulting anode material demonstrates high thermal conductivity which will enhance heat removal from the battery cell, thereby reducing the risk of overheating during rapid charge/discharge cycles. The thermal conductivity of the anode may be in the range of 25 w/m-K to 1000 w/m-K, and preferably in excess of 600 w/m-K, depending on the selection and respective loadings of carbon nanomaterials.

In order that the invention may be more readily understood, reference is made to the following examples, which are intended to be illustrative of the invention, but are not intended to be limiting in scope.

### EXAMPLE 1

Samples of carbon nanofiber powder were formed by de-bulking carbon nanofibers (PR-25-XT-PS from Applied Sciences, Inc.) into a pelletized form using wet mixing or powder processing methods. The powder samples were exposed to carbon dioxide at a temperature of about 950° C. for 2 hours at a carbon dioxide flow rate of 2 liters per minute (LPM) to increase the surface area and porosity prior to coating with silicon.

Table 1 below shows the effect of this form of oxidation under various conditions on the surface area of the carbon nanofibers prior to coating with silicon.

TABLE 1
Effect of carbon dioxide oxidation on the surface of carbon nanofibers

| | Surface area | Pore volume | Avg. Pore diameter |
|---|---|---|---|
| | (m²/g) | (cm³/g) | (nm) |
| Carbon nanofiber | 68 | 0.14 | 8.2 |
| powder (baseline) | | | |
| Carbon nanofiber | 181 | 0.28 | 6.1 |
| powder (CO₂ | | | |
| etched) | | | |

The sample of carbon dioxide treated nanofiber powder was then coated with silicon by exposure to silane gas at 500° C. for 10 minutes where the silane flow rate was 2 LPM. The silicon coated sample was then cycled against lithium metal in a half coin cell configuration. Comparison of the electrochemical performance of the non-oxidized baseline and the CO₂ oxidized carbon nanofiber powder indicated that increasing the surface area and pore volume of the carbon nanofiber powder improves the performance through the first several cycles.

### EXAMPLE 2

To study the effect of oxidation of the silicon coating on electrochemical performance, several strips of carbon nanofiber (CNF) veil samples obtained from Applied Sciences, Inc. were coated with silicon by exposure to silane gas at 500° C. for 15 minutes and split into two groups. One group was tested as-is while the other group received an oxidation treatment in air at 200° C. for 4 hours. The electrochemical performance of the two groups was evaluated in a coin half-cell configuration. The oxidized sample showed a capacity retention of 74% between cycles 2 to 51, which was an improvement over the non-oxidized sample, which showed a capacity retention of 62%.

### EXAMPLE 3

A nanomat comprised of carbon nanofibers from Applied Sciences, Inc. was coated with silicon by exposure to silane gas at a temperature of 500° C. for 2 minutes and was then coated on its exterior with a 5-10 nm thick layer of carbon by magnetron sputtering over the silicon-coated surface. The sample retained close to 80% of its initial capacity in about 200 cycles.

### EXAMPLE 4

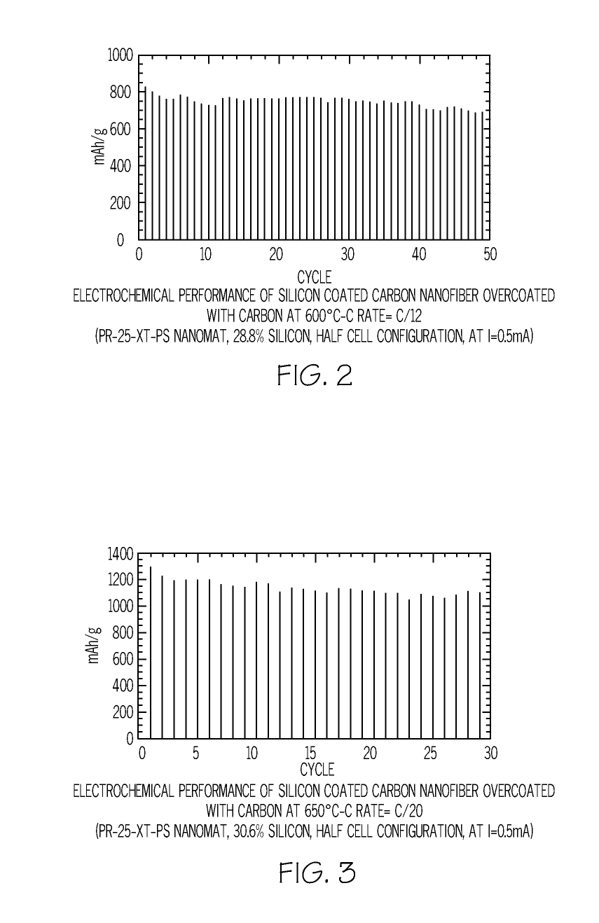

Samples of PR-25-XT-PS carbon nanofibers (from Applied Sciences, Inc.) were formed into a nanomat by dispersion with a solvent using sonication. Following dispersion, the carbon material suspension was poured over a vacuum-assisted filtration system. Preforms were allowed to dry in the system and were then collected. The preforms were then coated with silicon by exposure to silane gas at a temperature of 500° C. for a period of 5 minutes. The samples were lien coated with carbon at 600° C. and 650° C., respectively, by exposure to acetylene or a period of one hour. Anodes produced by this method were then electrochemically tested in a half cell configuration. The cycling data in FIGS. 2 and 3 clearly indicate the benefit of the carbon coating as they exhibited cycling efficiencies near 99.8% through 50 cycles. An additional sample was coated with silicon under the same reaction conditions but was not coated with the carbon overcoat. The sample was also electrochemically tested but failed catastrophically after about 40 cycles.

### EXAMPLE 5

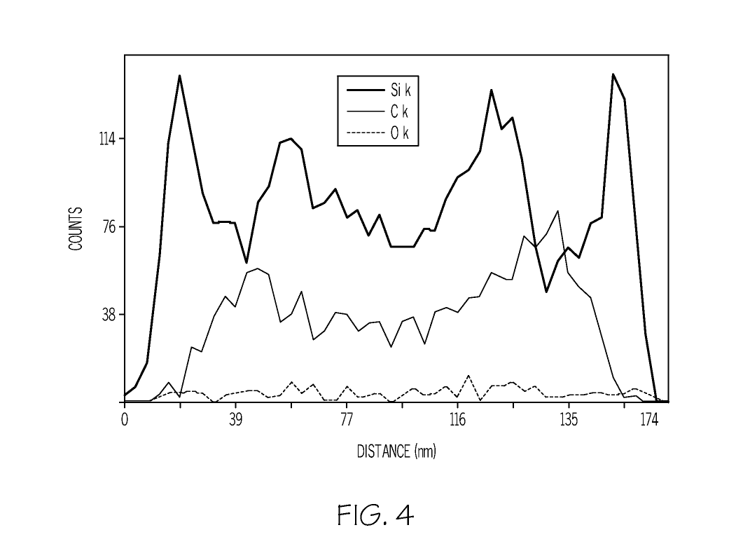

Samples of PR-25-XT-PS carbon nanofibers from Applied Sciences, Inc. were coated with silicon by exposure to silane gas at a temperature of 465° C. for a period of 30 minutes. The chemical composition of the coated carbon nanofibers was obtained from an energy-dispersive S-ray spectroscopy (EDS) line scan across the diameter of the coated fiber. The regions corresponding to the inner surface of the fiber showed a high concentration of silicon. The thickness of the silicon layers (obtained from EDS line scan profiles) were shown to be about 15 nm for the inner layer and about 10 nm for the outer layer. FIG. 4 illustrates the results of the EDS line-scan taken across the fiber and shows the concentration and distribution of Si, C, and O.

### EXAMPLE 6

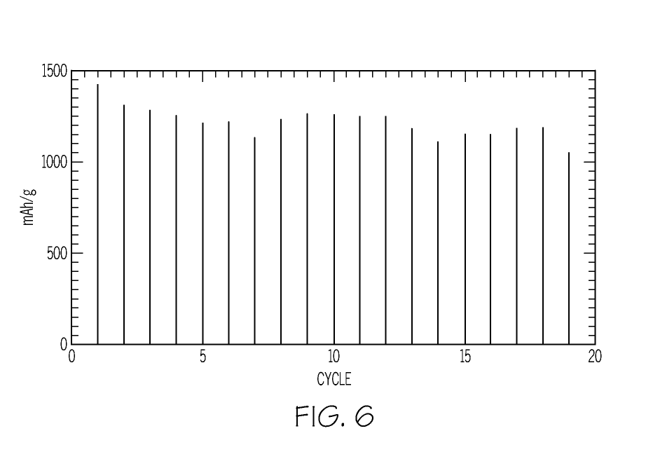

A sample of PR-25-XT-PS carbon nanofibers from Applied Sciences, Inc. were formed into a nanomat by dispersion with a solvent using sonication. Following dispersion, the carbon nanomaterial suspension was poured over a vacuum-assisted filtration system. Preforms were allowed to dry in the system and were then collected. The preforms were then coated with silicon by exposure to silane gas at a temperature of 500° C. for 3 minutes. The sample was then coated with carbon at 600° C. by exposure to acetylene for a period of 2.5 hours. After the first carbon coating was applied, the sample was coated with silicon a second time by exposure to silane gas at a temperature of 500° C. for 3 minutes. The sample was then coated a second time with carbon at 600° C. by exposure to acetylene for a period of 2.5 hours. Anodes produced by this method were then electrochemically tested in a half cell configuration. The cycling data in FIG. 6 indicates the benefit of alternating silicon and carbon coatings as they exhibited a capacity retention of over 1000 mAh/g up to 20 cycles.

Having described the invention in detail and by reference to preferred embodiments thereof, it will be apparent that modifications and variations are possible without departing from the scope of the invention.

What is claimed is:

1. A method of depositing silicon on the interior and exterior surfaces of a carbon nanomaterial comprising:
providing a carbon nanomaterial selected from vapor grown carbon nanofibers, a carbon nanomat, and a powder comprising carbon nanofibers;
flowing a silicon-containing precursor gas in contact with said carbon nanomaterial for a time sufficient for said gas to decompose and form a silicon coating on said surfaces of said carbon nanomaterial.

2. The method of claim 1 wherein said silicon is coated onto said carbon nanomaterial at a thickness of about 2 to 100 nm.

3. The method of claim 1 wherein said silicon is coated onto said carbon nanomaterial at a thickness of about 20 to 50 nm in thickness.

4. The method of claim 1 wherein said precursor gas is flowed in contact with said carbon nanomaterial at a temperature between about 400° C. to about 1200° C.

5. The method of claim 1 wherein said precursor gas is flowed in contact with said carbon nanomaterial at a temperature between about 400° C. to about 700° C.

6. The method of claim 1 wherein said precursor gas comprises silane, a blend of silane and hydrogen, or a blend of silane and an inert gas.

7. The method of claim 1 wherein said silicon coating comprises crystalline silicon or amorphous silicon.

8. The method of claim 1 wherein said silicon coating comprises amorphous silicon.

9. The method of claim 1 wherein said carbon nanomaterial has an average length of from about 1 to about 500 micrometers.

10. The method of claim 1 wherein said carbon nanomaterial has an average length of from about 10 to about 100 microns.

11. The method of claim 1 further including exposing said silicon-coated nanomaterial to an oxidizing gas for a time sufficient to oxidize said silicon coating and form a silicon oxide coating.

12. The method of claim 11 wherein said oxidizing gas is selected from oxygen and carbon dioxide.

13. The method of claim 11 wherein said silicon-coated nanomaterial is exposed to said oxidizing gas at a temperature of about 200° C.

14. The method of claim 1 further including applying a protective carbon coating to said silicon-coated carbon nanomaterial.

15. The method of claim 14 wherein said carbon coating is applied by carbonization, chemical vapor deposition, or magnetron sputtering.

16. The method of claim 15 wherein said carbon coating is applied by magnetron sputtering to a thickness of about 5 to 10 nm.

17. The method of claim 14 including providing a plurality of alternating layers of silicon and carbon on said carbon nanomaterial.

18. The method of claim 1 including heating said carbon nanomaterial at a temperature between about 100° C. to about 1200° C. in the presence of an oxidizing gas for a time sufficient to increase the surface area of said carbon nanomaterial prior to depositing said silicon coating.

19. The method of claim 18 wherein said oxidizing gas is selected from carbon dioxide and oxygen.

20. The method of claim 1 further including forming an anode by blending said silicon-coated carbon nanomaterial with a binder.

21. The method of claim 20 wherein said binder is selected from polyvinylidene fluoride, furfuryl alcohol, and polystyrene.

22. An anode formed by the method of claim 20 for use in a lithium ion battery.

23. The anode of claim 22 having an electrical conductivity of from about 0.01 to about 0.5 ohm/cm.

24. The anode of claim 22 having an irreversible capacity of from less than about 5% to 40% of total capacity.

25. The anode of claim 22 having a reversible capacity of at least 450 mAH/g.

26. The anode of claim 22 having a reversible capacity of at least 1000 mAH/g.

27. The anode of claim 22 having a thermal conductivity of at least 50 w/m-K up to 1000 w/m-K.
